(19) United States
(12) Patent Application Publication
(10) Pub. No.: US 2023/0387617 A1
(43) Pub. Date: Nov. 30, 2023

(54) THERMAL MANAGEMENT STRUCTURES FOR POWER CONNECTOR

(71) Applicant: Molex, LLC, Lisle, IL (US)

(72) Inventor: Ronald C. Hodge, Montgomery, IL (US)

(21) Appl. No.: 18/032,354

(22) PCT Filed: Nov. 8, 2021
(86) PCT No.: PCT/IB2021/060297

§ 371 Date: Apr. 18, 2023

Related U.S. Application Data
(60) Provisional application No. 63/111,103, filed on Nov. 9, 2020.

(51) Int. Cl. H01R 12/72; H05K 1/02; H01R 12/73

(52) U.S. Cl. CPC H01R 12/727; H05K 1/0209; H01R 12/73; H05K 1/021

(57) ABSTRACT

A power connector includes first and second board mounted connectors which are configured to transmit power. The boards to which the connectors are mounted have an increased trace size. Each connector includes a dielectric housing having an assembly mounted within a passageway of the housing. The assembly includes a pair of terminals and a heat sink mounted between the terminals. One of the housings include openings which are in fluid communication with passageways in the heat sinks for allowing cooling air to flow therethrough.

### RELATED APPLICATIONS

This application claims priority to U.S. Provisional Application No. 63/111,103 filed Nov. 9, 2020, which is incorporated herein by reference.

### FIELD OF THE DISCLOSURE

This disclosure relates to the field of transfer of thermal energy from a power connector, more specifically to a board mounted power connector.

### DESCRIPTION OF RELATED ART

Currently, electrical connectors transmit power and signal through a contact interface typically comprising a female receptacle connector and a male blade connector. The terminals are from a conductive material, such as a copper-based alloy. These connectors can be mounted on a circuit board and used in a high-power application. The connectors are limited in current carrying due to temperature rise across the contact interface. These connectors typical rely on air flow to manage the temperature rise. Improvements to these connectors can increase current carrying and result in higher rated connectors.

### BRIEF SUMMARY

In an embodiment, a power connector includes first and second board mounted connectors which are configured to transmit power. The boards to which the connectors are mounted have an increased trace size. Each connector includes a dielectric housing having an assembly mounted within a passageway of the housing. The assembly includes a pair of terminals and a heat sink mounted between the terminals. One of the housings include openings which are in fluid communication with passageways in the heat sinks for allowing cooling air to flow therethrough.

In an embodiment, a connector which is configured to transmit power includes a dielectric housing having a passageway therethrough extending from a front end thereof to a rear end thereof, and an assembly mounted within the passageway. The assembly includes a pair of terminals mounted within the passageway and a heat sink mounted between the terminals. Each terminal has a body portion positioned within the passageway and a terminal engaging portion extending from the body portion. The body portions are adjacent to each other and are spaced apart from each other. The terminal engaging portions are adjacent to each other, and the heat sink is positioned between the body portions and extends outward from the passageway of the housing.

In an embodiment, a power connector which includes a first connector and a second connector is provided. The first connector includes a first dielectric housing having a plurality of walls defining a plurality of passageways therethrough extending from a front end thereof to a rear end thereof, and a plurality of openings through one of the walls, respective openings being in fluid communication with the respective passageways, and a first assembly mounted within each passageway. Each first assembly includes a pair of terminals mounted within the respective passageway and a heat sink mounted between the terminals. Each terminal has a body portion positioned within the passageway and a terminal engaging portion extending from the body portion. The body portions are adjacent to each other and are spaced apart from each other. The terminal engaging portions are adjacent to each other, and the heat sink are positioned between the body portions and extend outward from the passageway of the housing. The heat sink of each assembly has an opening therethrough which extends from a front end thereof to a rear end thereof. The respective opening in the housing is in fluid communication with the opening through the respective heat sink. The second connector includes a second dielectric housing having a plurality of walls defining a plurality of passageways therethrough extending from a front end thereof to a rear end thereof, and a second assembly mounted within each passageway of the second housing. Each second assembly includes a pair of terminals mounted within the respective passageway and a heat sink mounted between the terminals. Each terminal of the second assembly has a body portion positioned within the passageway of the second housing and a terminal engaging portion extending from the body portion of the second assembly. The body portions of the second assembly are adjacent to each other and are spaced apart from each other. The terminal engaging portions of the second assembly are adjacent to each other, and the heat sink of the second assembly is positioned between the body portions of the second assembly and extend outward from the passageway of the housing of the second assembly. The terminal engaging portions of the second assembly are configured to mate with the terminal engaging portions of the first assembly.

### BRIEF DESCRIPTION OF THE DRAWINGS

The present disclosure is illustrated by way of example, and not limited, in the accompanying figures in which like reference numerals indicate similar elements and in which:

FIG. 1 depicts a top plan view of a power connector mounted on printed circuit boards;

FIG. 2 depicts a perspective view of the power connector and a portion of the printed circuit boards;

FIG. 3 depicts a top plan view of a portion of the printed circuit boards;

FIG. 4 depicts a front perspective view of a housing of one of a first connector of the power connector, viewed from the top;

FIG. 5 depicts a front perspective view of the housing of FIG. 4, viewed from the bottom;

FIG. 6 depicts a rear end elevation view of the housing of FIG. 4;

FIG. 7 depicts a perspective view of a pair of terminals used with the housing of FIG. 4;

FIG. 8 depicts a top plan view of the pair of terminals of FIG. 7;

FIG. 9 depicts a front perspective view of a heat sink used with the housing of FIG. 4;

FIG. 10 depicts a rear perspective view of the heat sink of FIG. 9;

FIG. 11 depicts a cross-section taken through FIG. 1;

FIG. 12 depicts a perspective view of a pair of terminals used with the housing of the other connector of the power connector;

FIG. 13 depicts a top plan view of the pair of terminals of FIG. 12; and

FIG. 14 depicts a cross-section taken through FIG. 1.

### DETAILED DESCRIPTION

The appended drawings illustrate embodiments of the present disclosure and it is to be understood that the disclosed embodiments are merely exemplary of the disclosure, which may be embodied in various forms. Therefore, specific details disclosed herein are not to be interpreted as limiting, but merely as a basis for the claims and as a representative basis for teaching one skilled in the art to variously employ the present disclosure.

As can be appreciated from accompanying description and illustrations, a power connector 20 is provided which includes structure utilized to increase heat dissipation, thereby increasing current carrying and thus increasing the rating of the power connector 20. Accordingly, a broad range of usages is provided for the power connector 20.

The power connector 20 includes a first connector 22, which is a female receptacle, and a second connector 222, which is a male plug. The power connector 20 is mounted on printed circuit boards 26, 226. The first connector 22 is mounted on a first printed circuit board 26 and the second connector 222 is mounted on a second printed circuit board 226. The power connector 20 includes structures which increase the transfer of thermal energy out of the power connector 20. All the structures can be used by themselves, or in any combination thereof.

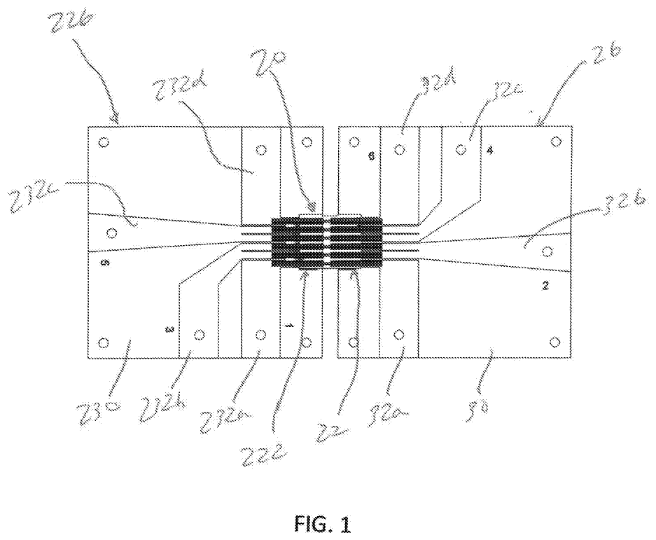

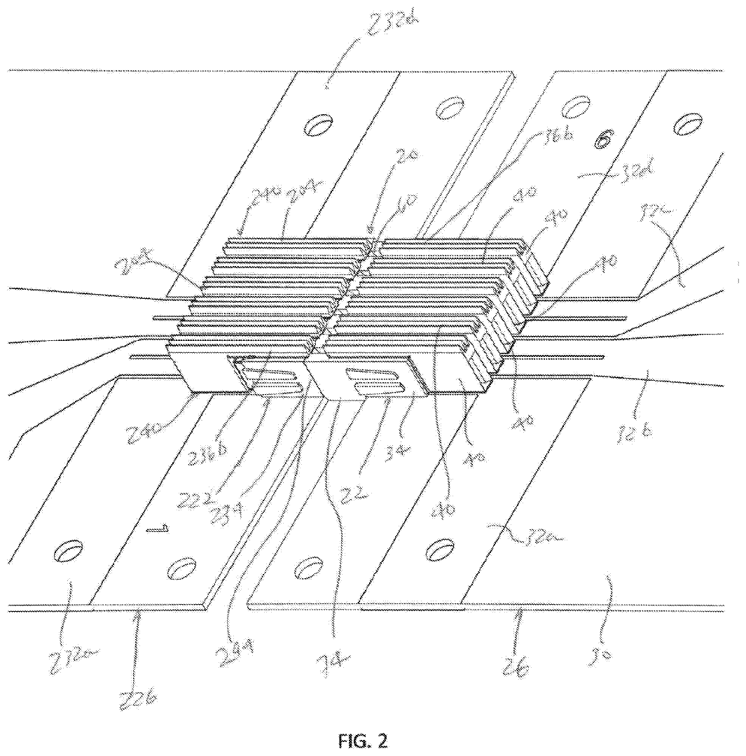

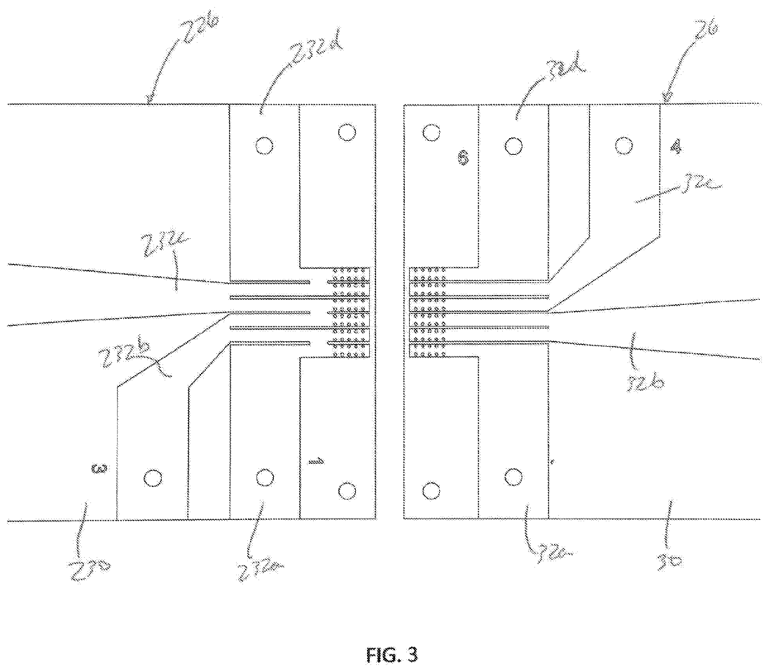

As shown in FIG. 1-3, the printed circuit board 26 is formed of a planar substrate 30 on which a plurality of electrical trace sections 32a, 32b, 32c, 32d which are sized by thickness and area are provided. In the present disclosure, the size of the trace sections 32a, 32b, 32c, 32d are increased to provide a greater surface area to dissipate heat to the surroundings from each trace section 32a, 32b, 32c, 32d. The greater cross-section of each trace section 32a, 32b, 32c, 32d also allows more current travel through each trace section 32a, 32b, 32c, 32d. This provides part of the first such structure which increases the transfer of thermal energy out of the power connector 20 when the power connector 20 is mounted to the printed circuit board 26.

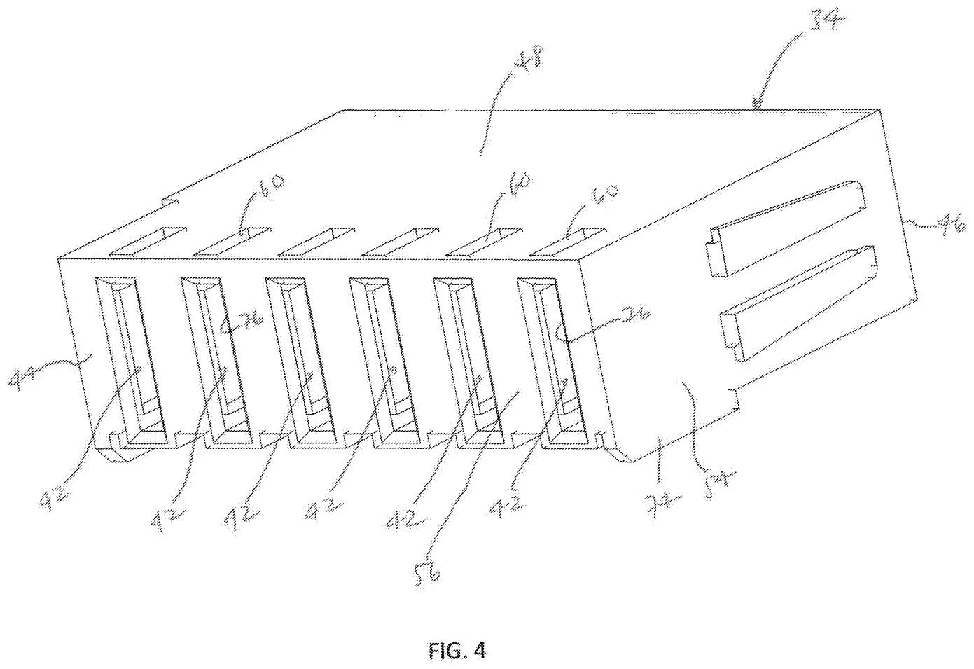

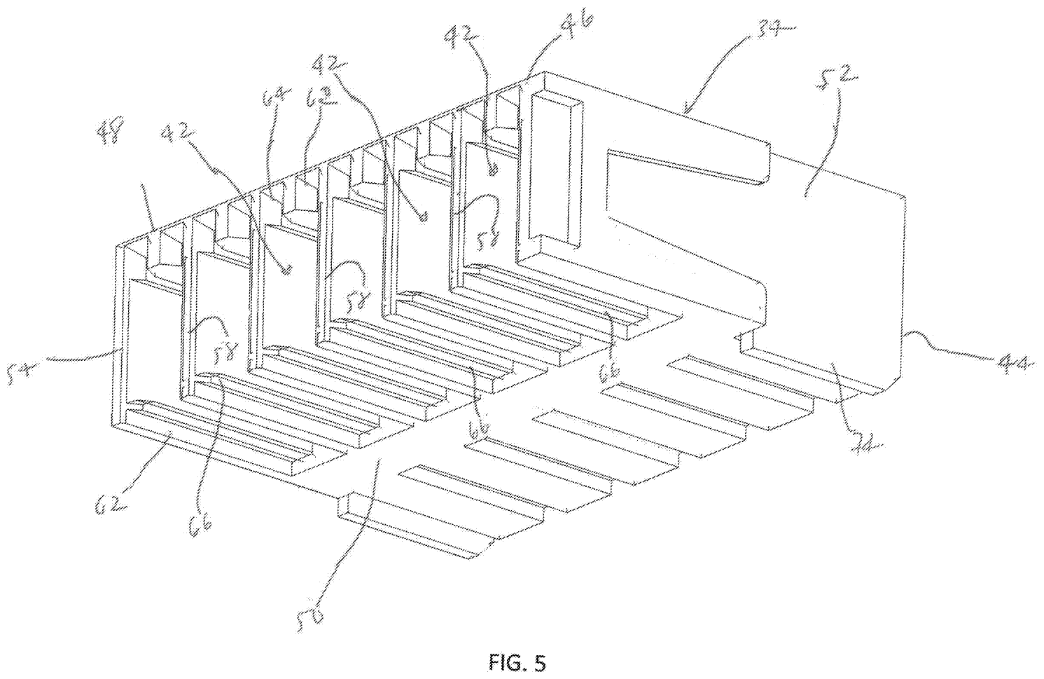

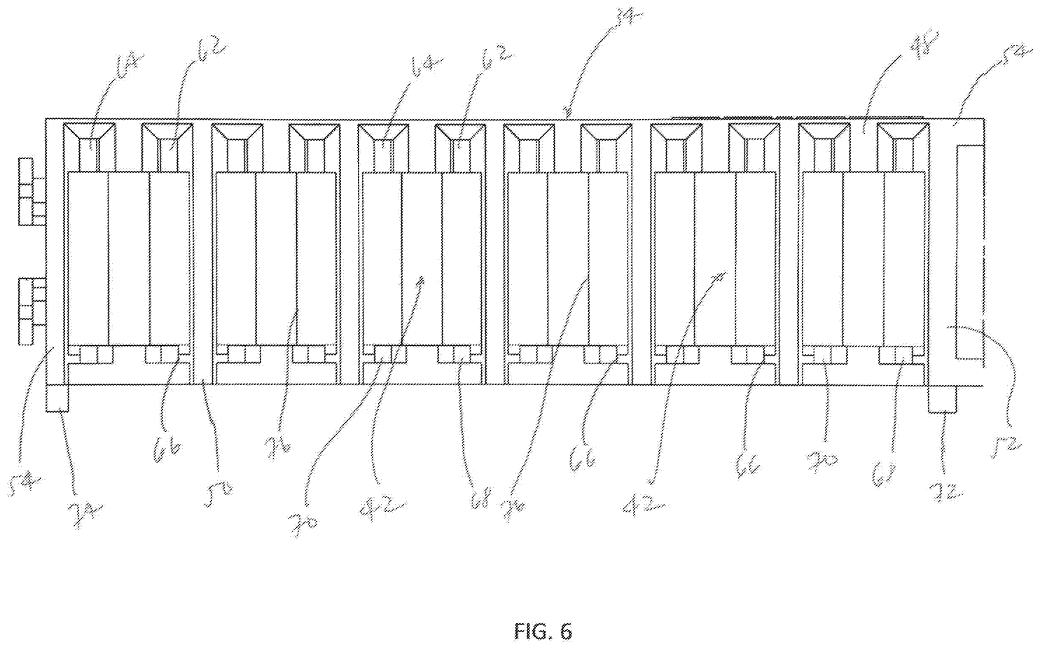

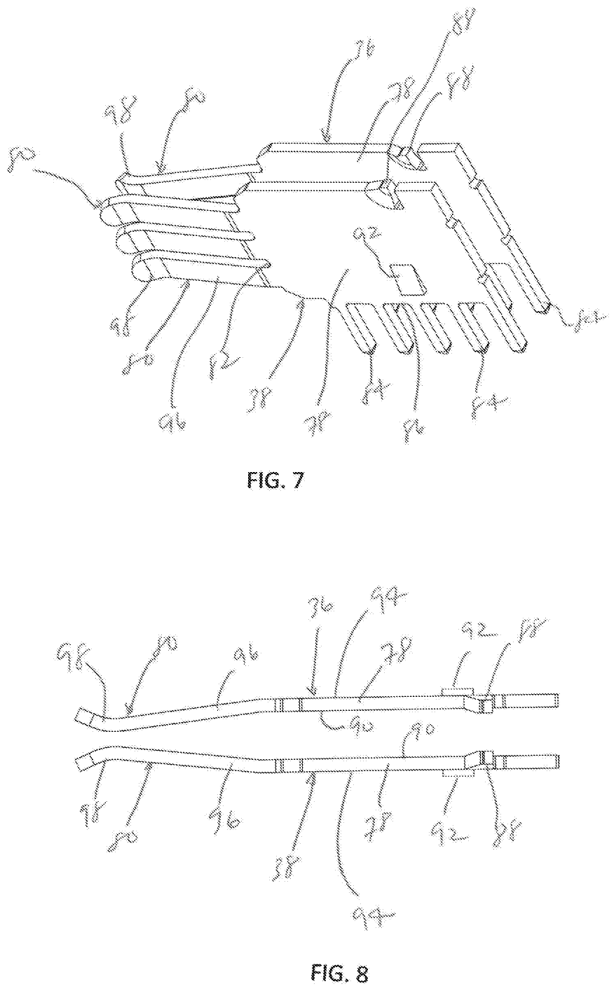

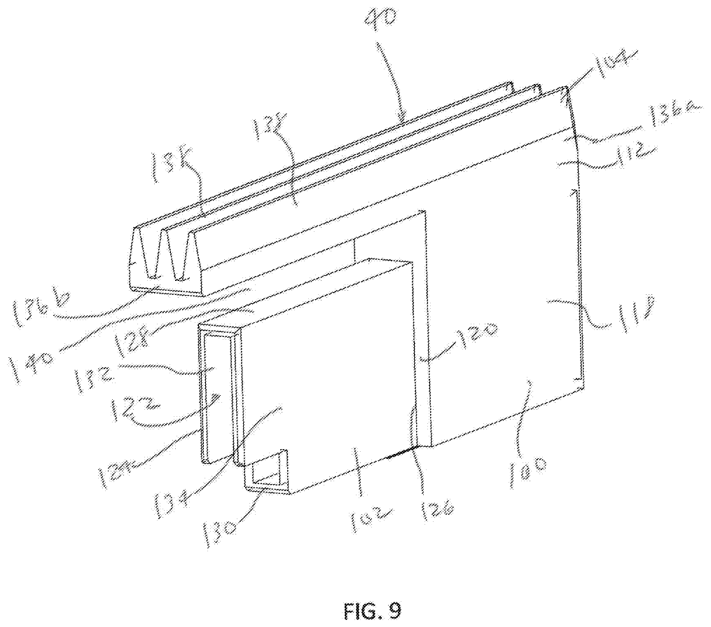

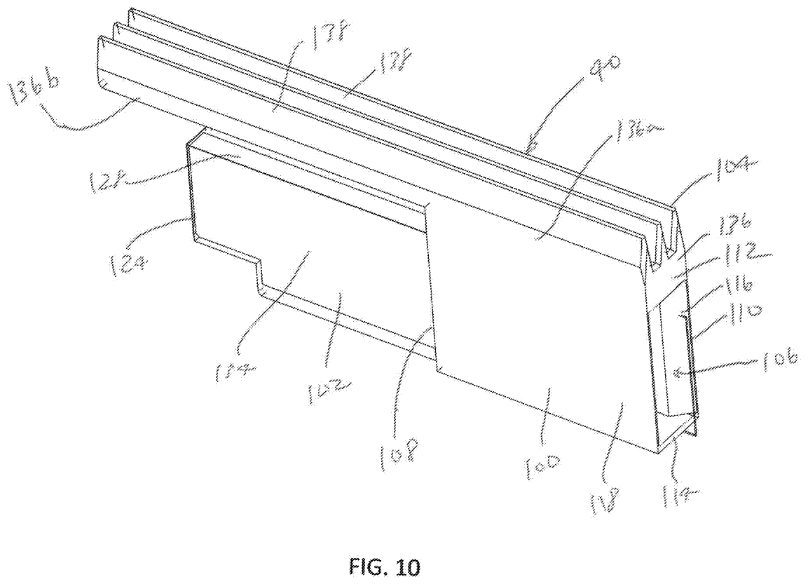

The first connector 22 of the power connector 20 includes a dielectric housing 34 as shown in FIGS. 4-6, a plurality of pairs of conductive terminals 36, 38, as shown in FIGS. 7 and 8, mounted within the housing 34, and a plurality of conductive heat sinks 40, as shown in FIGS. 9 and 10, mounted between the pairs of terminals 36, 38. Each pair of terminals 36, 38 and the heat sink 40 mounted therebetween forms an assembly. In each assembly, the heat sink 40 conducts heat from the terminals 36, 38 and provides part of a second structure which increases the transfer of thermal energy out of the power connector 20. While a plurality of pairs of conductive terminals 36, 38 and a plurality of conductive heat sinks 40 are shown and described, the first connector 22 can have a single pair of conductive terminals 36, 38 and a single conductive heat sink 40.

The housing 34, see FIGS. 4-6, has a plurality of longitudinally extending passageways 42 which extend from a front end 44 of the housing 34 to a rear end 46 of the housing 34. The passageways 42 are defined by a top wall 48, an opposite bottom wall 50 which is parallel to the top wall 48, opposite longitudinally extending side walls 52, 54 extending between the top and bottom walls 48, 50, a front wall 56 at front ends of the walls 48, 50, 52, 54, and dividing walls 58 extending between the top and bottom walls 48, 50 from the rear end 46 to the front wall 56. The side walls 52, 54 and the dividing walls 58 are parallel to each other.

The top wall 48 has a plurality of spaced apart longitudinally extending openings 60 therethrough which are proximate to, but spaced from, the front wall 56. Respective ones of the openings 60 are in fluid communication with respective ones of the passageways 42. The top wall 48 has plurality of pairs of longitudinally extending spaced apart recesses 62, 64 which extend from the rear end 46 toward the front wall 56 and are in fluid communication with respective ones of the passageways 42.

The bottom wall 50 has a plurality of spaced apart longitudinally extending slots 66 which extend from the rear end 46 toward the front wall 56 and are in fluid communication with respective ones of the passageways 42. The slots 66 extend approximately to the midpoint of the bottom wall 50. At the front end of each slot 66, a pair of longitudinally extending spaced apart recesses 68, 70 are provided in the bottom wall 50 and are in fluid communication with respective ones of the passageways 42.

The recesses 62 vertically align with the recesses 68, and the recesses 64 vertically align with the recesses 70. Front ends of the recesses 62, 64, 68, 70 align with each other along the length of the housing 34.

A flange 72 extends down from the side wall 52, and a flange 74 extends down from the side wall 54. Each flange 72, 74 extends from the front end 44. The flanges 72, 74 extend along a portion of the length of the housing 34.

The front wall 56 has a plurality of openings 76 therethrough which form a front end of each passageway 42.

Each terminal 36, 38, see FIGS. 7 and 8, may be formed of metal, and has a planar body portion 78 having a plurality of spaced apart flexible fingers 80 extending from a front edge 82 thereof and a plurality of spaced apart pins 84 extending from a bottom edge 86 thereof. An upper tab 88 extends from a first side surface 90 of the body portion 78 at an upper end thereof, and a lower tab 92 extends from a second, opposite side surface 94 of the body portion 78 proximate to the lower edge 86 thereof. Each finger 80 has a rear portion 96 which extends from the front edge 82 of the body portion 78, and a front portion 98 extending from a front end of the rear portion 96. The rear portion 96 extends at an angle from the body portion 78. The front portion 98 is curved. When the pairs of terminals 36, 38 are next to each other, the body portions 78 are parallel to each other, the first side surfaces 90 face each other, and the rear portions 96 angle toward each other with the base of the curved front portions 98 closest to each other. The tabs 88 angle toward each other, and the tabs 92 are on opposite sides of the terminals 36, 38 from each other.

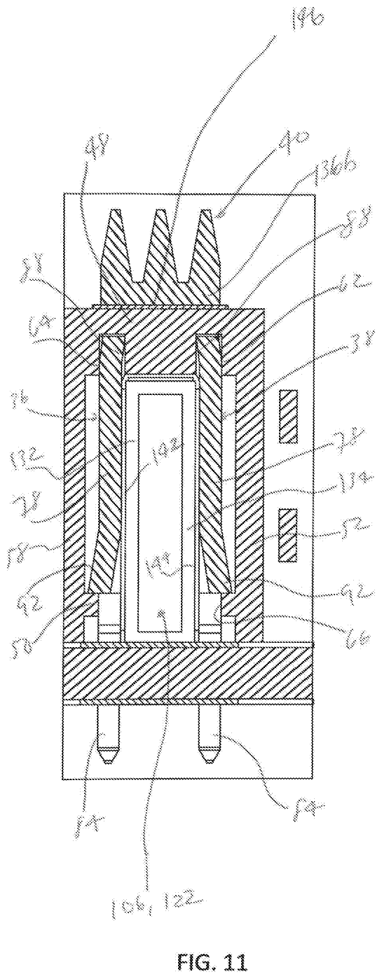

An assembly is seated within each passageway 42. For each assembly, an upper end of the body portion 78 of terminal 36 seats within recess 62 and a lower end of the body portion 78 of terminal 36 seats within recess 68. A rear end of the body portion 78 of terminal 36 generally aligns with the rear end 46 of the housing 34. The fingers 80 of terminal 36 extend forward within the passageway 42, but do not pass the front wall 56. The pins 84 extend through the slot 66 and vertically downward from the bottom wall 50 of the housing 34. The upper tab 88 engages with a vertical wall of the recess 62 and the lower tab 92 engages with an upper surface of the bottom wall 50, see FIG. 11. The engagement of the tabs 88, 92 with the housing 34 locks the terminal 36 into position within the housing 34. Likewise, for each assembly, an upper end of the body portion 78 of terminal 38 seats within recess 64 and a lower end of the body portion 78 of terminal 38 seats within recess 70. A rear end of the body portion 78 of terminal 38 generally aligns with the rear end 46 of the housing 34. The fingers 80 of terminal 38 extend forward within the passageway 42, but do not pass the front wall 56. The pins 84 of terminal 38 extend through the slot 66 and vertically downward from the bottom wall 50 of the housing 34. The upper tab 88 engages with a vertical wall of the recess 64 and the lower tab 92 engages with an upper surface of the bottom wall 50. The engagement of the tabs 88, 92 with the housing 34 locks the terminal 38 into position within the housing 34. The first side surface 90 of the body portions 78 of the terminals 36, 38 are spaced apart from each other by a space. Front ends of the fingers 80 of the terminals 36, 38 are vertically below the openings 60, but are spaced to opposite sides of the opening 60.

Each heat sink 40, see FIGS. 9 and 10, has a main body portion 100, a projecting body portion 102, and a fin portion 104. The heat sink 40 may be constructed from cast aluminum, but other constructions are contemplated, such as extruded, or machined type.

The main body portion 100 has a longitudinally extending passageway 106 extend from a front end 108 of the main body portion 100 to a rear end 110 of the main body portion 100. The passageway 106 is defined by a top wall 112, an opposite bottom wall 114 which is parallel to the top wall 112, opposite longitudinally extending side walls 116, 118 extending between the top and bottom walls 112, 114, and a front wall 120 at front ends of the walls 112, 114, 116, 118. The side walls 116, 118 are parallel to each other. The front wall 120 has an opening therethrough which forms a front end of the passageway 106.

The projecting body portion 102 has a longitudinally extending passageway 122 extend from a front end 124 of the projecting body portion 102 to a rear end 126 of the projecting body portion 102. The passageway 122 is defined by a top wall 128, an opposite bottom wall 130 which is parallel to the top wall 128, and opposite longitudinally extending side walls 132, 134 extending between the top and bottom walls 128, 130. The top wall 128 extends from the front wall 120 above the opening forming the front end of the passageway 106. The bottom wall 130 is parallel to the top wall 128 and extends from the front wall 120 below the opening forming the front end of the passageway 106. The side walls 132, 134 are parallel to each other and each extends from the front wall 120 to the respective sides of the opening forming the front end of the passageway 106. The front wall 120 partially exposed outward of the projecting body portion 102.

The passageway 106 through the main body portion 100 and the passageway 122 through the projecting body portion 102 longitudinally align with each other to form a continuous passageway from the front end 124 of the projecting body portion 102 to the rear end 110 of the main body portion 100.

The fin portion 104 has a base portion 136 having a rear portion 136a extending upward from the top wall 112 and a front portion 136b which extends forward from the front end 108 of the top wall 112. A plurality of fins 138 extend upward from the base portion 136. The fins 138 are arranged to conduct heat away from the terminals 36, 38 when mounted thereto and to dissipate heat by convection. In an embodiment as shown in the drawings, the fins 138 are elongated ribs having elongated channels formed therebetween. In an alternative embodiment (not shown), the fins 138 are formed in an array of pillars. This construction includes hollow spaces in the internal portions of the heat sinks for improved air flow. A lower surface of the front portion 136b is spaced from an upper surface of the top wall 128 of the projecting body portion 102 by a space 140.

For each assembly, the projecting wall portion 102 seats between the first side surface 90 of the body portion 78. Side wall 132 is adjacent to terminal 36, and wall 134 is adjacent to terminal 38. The side wall 132 may directly contact the first side surface 90 of the body portion 78 of terminal 36 or a Thermal Interface Material (TIM) 142 may be positioned between the side wall 132 and the first side surface 90. The side wall 134 may directly contact the first side surface 90 of the body portion 78 of terminal 38 or a Thermal Interface Material (TIM) 144 may be positioned between the side wall 134 and the first side surface 90. The projecting wall portion 102 does not extend between the fingers 80 so that the fingers 80 are free to deflect without interference from the heat sink 40. The front wall 120 of the main body portion 100 abuts against the rear end 46 of the housing 34 and the main body portion 100 and the rear portion 136a of the fin portion 104 are rearward of the housing 34. The front portion 136b of the fin portion 104 extends longitudinally over the top wall 48 of the housing 34, but does not cover the openings 60. The top wall 48 seats within the space 140. The front portion 136a of the fin portion 104 may directly contact the upper surface of the top wall 48 or a Thermal Interface Material (TIM) 146 may be positioned between the front portion 136a and the top wall 48. The adjacent heat sinks 40 are spaced apart from each other along the width of the housing 32 such that a portion of the top wall 48 is exposed between adjacent front portions 136b.

The Thermal Interface Material (TIM) 142, 144, 146 may have carbon nanotube technology to increase the thermal transfer between the heat sink 40 and the terminals 36, 28. Materials such as thermal grease, copper foil and the like are also effective Thermal Interface Material (TIM), and may be used. The first connector 22 seats on top of the electrical traces 32a, 32b, 32c, 32d of the printed circuit board 30 such that each electrical traces 32a, 32b, 32c, 32d thereunder is partially covered by at least one of the assemblies formed by the terminals 36, 38 and the heat sink 40. Some of the traces 32a, 32b, 32c, 32d may have two or more assemblies thereon, as shown for example by traces 32b, 32c. The assembly formed of the terminals 36, 38 and the heat sink 40 define a width between the side surfaces 94 of the body portions 78 of the terminals 36, 38. Each trace 32a, 32b, 32c, 32d has a width defined under where the assembly is mounted that is greater than the width defined by the assembly. The remainder of the trace 32a, 32b, 32c, 32d may have a width between side edges that is greater than the width defined under where the assembly is mounted. In addition, the thickness of each trace 32a, 32b, 32c, 32d can be increased. The flanges 72, 74 are in front of a front edge of the printed circuit board 26. The pins 84 extend through plated vias in the printed circuit board 26 that are electrically connected to the traces 32a, 32b, 32c, 32d.

The printed circuit board 226 is formed of a planar substrate 230 on which a single electrical trace is provided and is formed of a plurality of electrical trace sections 232a, 232b, 232c, 232d which are sized by thickness and area. In the present disclosure, the size of the trace sections 232a, 232b, 232c, 232d are increased to provide a greater surface area to dissipate heat to the surroundings from each trace section 232a, 232b, 232c, 232d. The greater cross-section of each trace section 232a, 232b, 232c, 232d also allows more current travel through trace sections 232a, 232b, 232c, 232d. This provides part of the first such structure which increases the transfer of thermal energy out of the power connector 20 when the power connector 20 is mounted to the printed circuit board 226.

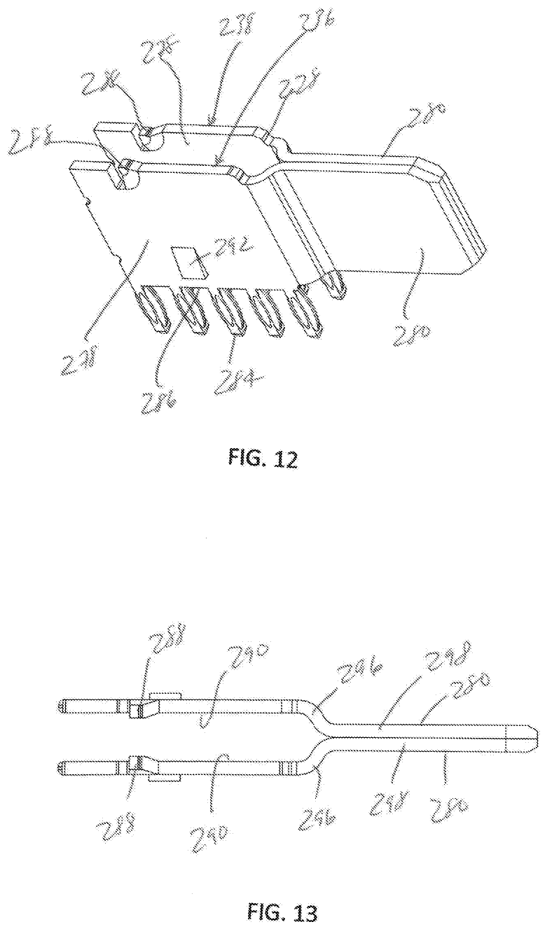

The second connector 222 of the power connector 20 includes a dielectric housing 234, a plurality of pairs of conductive terminals 236, 238, see FIGS. 12 and 13, mounted within the housing 234, and a plurality of conductive heat sinks 240 mounted between the pairs of terminals 236, 238. Each pair of terminals 236, 238 and the heat sink 240 mounted therebetween forms an assembly like that of the first connector 22. In each assembly, the heat sink 240 conducts heat from the terminals 236, 238 and provides a part of the second structure which increases the transfer of thermal energy out of the power connector 20. While a plurality of pairs of conductive terminals 236, 238 and a plurality of conductive heat sinks 240 are shown and described, the second connector 222 can have a single pair of conductive terminals 236, 238 and a single conductive heat sink 240. The housing 234 is identically formed to the housing 34 except that the openings 60 have been eliminated. As such a description of the housing 234 is not repeated, and identical components of housing 234 to that of housing 234 have the same reference numerals, except in the two hundreds. The heat sinks 240 are identically formed to heat sinks 40, except that the front portion 136b may be longer such that the front end of the front portion 236b may align with the front end 244 of the housing 234. As such, a description of the heat sinks 240 is not repeated. Identical components of heat sinks 240 to that of heat sinks 40 have the same reference numerals, except in the two hundreds.

Each terminal 236, 238 may be formed of metal, and has a planar body portion 278 having a single blade 280 extending from a front edge 282 thereof and a plurality of spaced apart pins 284 extending from a bottom edge 286 thereof. An upper tab 288 extends from a first side surface 290 of the body portion 278 at an upper end thereof, and a lower tab 292 extends from a second, opposite side surface 294 of the body portion 278 proximate to the lower edge 286 thereof. Each blade 280 has a rear portion 296 which extends from the front edge 282 of the body portion 278, and a front portion 298 extending from a front end of the rear portion 296. The rear portion 296 extends at an angle from the body portion 278. The front portion 298 is planar. When the pairs of terminals 236, 238 are next to each other, the body portions 278 are parallel to each other, the first side surfaces 290 face each other, the rear portions 296 angle toward each other, and the planar portions 298 abut against each other. The tabs 288 angle toward each other, and the tabs 292 are on opposite sides of the terminals 236, 238 from each other.

An assembly is seated within each passageway 242 in the same manner as the assembly is seated within each passageway 42, except that the blades 280 of the terminals 236, 238 pass through the opening 276 in the front wall 256.

It is to be understood that the pins form a coupling for coupling the terminals 36, 38, 236, 238 to the printed circuit boards 26, 28. Other forms of couplings, such as surface mounting, can be provided.

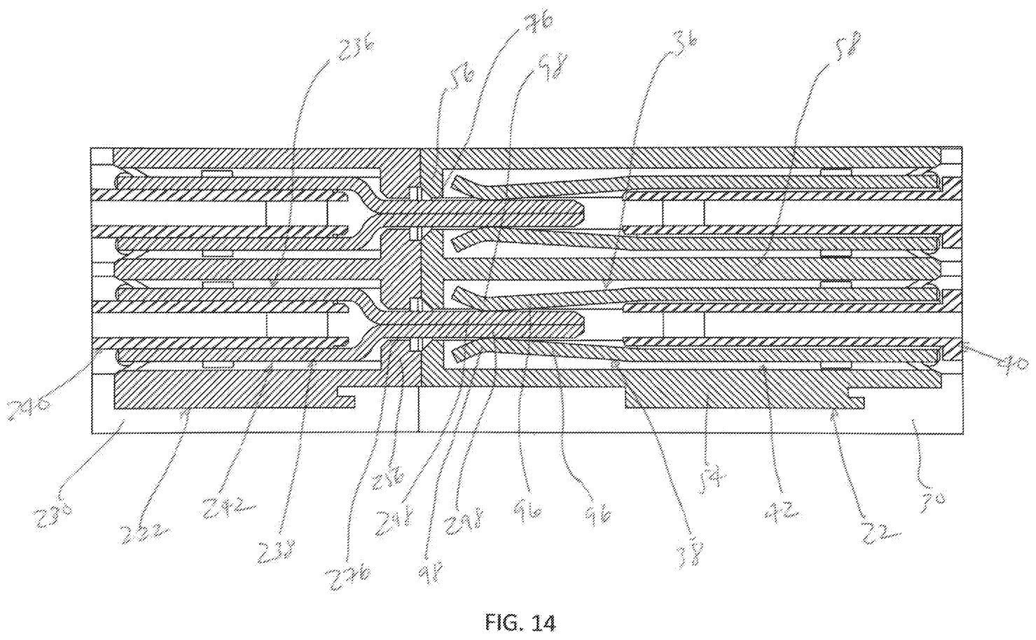

When the first printed circuit board 26 having the first connector 22 mounted thereon is mated with the second printed circuit board 226 having the second connector 222 mounted thereon, the blades 280 of each assembly of second connector 222 pass through the openings 76 and between the fingers 80 of the mating assembly in first connector 22 to form an electrical connection, see FIG. 14. The front end 44 of the first connector 22 abuts against the front end 244 of the second connector 222. The front ends of the front portions 136b are spaced from the front ends of the front portions 236b such that the openings 60 are not blocked. Air can flow through the passageways 42, 242 of the heat sinks 40, 240 and through the openings 60. This provides the third such structure which increases the transfer of thermal energy out of the power connector 20 by remove heated air from the power connector 20. This allows air to be directed across the hot portions of the terminals 36, 38, 236, 238 and exit the power connector through the openings 60. Additionally, the fin portions 104, 204 of the heat sinks 40, 240 are positioned close to the openings 60 to direct any airflow over the top of the power connector directly over the openings 60 and to use the Bernoulli effect to create a low pressure to help draw out the warmer air inside the power connector 20 and provide additional cooling.

The fingers 80 and the blades 280 form an example of terminal engaging portions. Other structures for mating the terminals 36, 38, 236, 238 are within the scope of the present disclosure.

The thermal management structures described above dissipate heat more effectively and provide for increased cooling. Since the current passing through the power connector 20 and the contact resistance in the terminals 36, 38, 236, 238 dictate the current based on an overall temperature rise, improved thermal management and a greater current can now pass with the same overall temperature rise. A larger current rating for the power connector 20 is achieved.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

We claim:

1. A connector configured to transmit power comprising:
a dielectric housing having a passageway therethrough extending from a front end thereof to a rear end thereof; and
an assembly mounted within the passageway, the assembly comprising a pair of terminals mounted within the passageway and a heat sink mounted between the terminals, each terminal having a body portion positioned within the passageway and a terminal engaging portion extending from the body portion, the body portions being adjacent to each other and spaced apart from each other, the terminal engaging portions being adjacent to each other, and the heat sink being positioned between the body portions and extending outward from the passageway of the housing.

2. The connector configured to transmit power of claim 1, further comprising a plurality of assemblies, and wherein the dielectric housing has a plurality of passageways therethrough, wherein one assembly is mounted within each passageway.

3. The connector configured to transmit power of claim 2, wherein the housing has a plurality of walls defining the plurality of passageways, and further comprising a plurality of openings through one of the walls, each opening being in fluid communication with the respective passageway.

4. The connector configured to transmit power of claim 3, wherein the heat sink in each assembly has a main body portion which is outward of the passageway, a projecting portion extending from the main body portion that seats between the pair of the terminals, and a plurality of fins extending from the main body portion, the fins extending over a portion of the housing but do not cover the openings.

5. The connector configured to transmit power of claim 1, wherein the heat sink has a main body portion which is outward of the passageway, a projecting portion extending from the main body portion that seats between the pair of the terminals, and a plurality of fins extending from the main body portion.

6. The connector configured to transmit power of claim 5, wherein the fins further extend over a portion of the housing.

7. The connector configured to transmit power of claim 5, wherein the fins are elongated ribs.

8. The connector configured to transmit power as defined in claim 1, wherein each terminal engaging portion comprises a plurality of flexible fingers.

9. The connector configured to transmit power as defined in claim 1, wherein each terminal engaging portion comprises a blade.

10. The connector configured to transmit power as defined in claim 1, in combination with a printed circuit board having traces coupled to the body portion of each terminal by a coupling, wherein each trace has a width which is greater than a width defined by the couplings and the heat sink.

11. The connector configured to transmit power as defined in claim 10, wherein the couplings are plurality of pins extending from the body portions which seat within apertures in the printed circuit board.

12. The connector configured to transmit power as defined in claim 1, wherein the heat sink directly engages with the body portions.

13. The connector configured to transmit power as defined in claim 1, further comprising a thermal insulating material between the heat sink and the body portions, the thermal insulating material directly engaging the body portions and the heat sink.

14. The connector configured to transmit power as defined in claim 1, wherein the housing has a plurality of walls defining the passageway, and further comprising an opening through one of the walls in fluid communication with the passageway.

15. The connector configured to transmit power as defined in claim 14, wherein the heat sink has an opening therethrough which extends from a front end thereof to a rear end thereof, and the opening in the housing is in fluid communication with the opening through the heat sink.

16. The connector configured to transmit power as defined in claim 1, in combination with a second connector configured to transmit power, the second connector comprising:
a second dielectric housing having a passageway therethrough extending from a front end thereof to a rear end thereof; and
a second assembly mounted within the passageway of the second housing and comprising a pair of terminals mounted within the passageway and a heat sink mounted between the terminals, each terminal of the second assembly having a body portion positioned within the passageway of the second housing and a terminal engaging portion extending from the body portion of the second assembly, the body portions of the second assembly being adjacent to each other and spaced apart from each other, the terminal engaging portions of the second assembly being adjacent to each other, and the heat sink of the second assembly being positioned between the body portions of the second assembly and extending outward from the passageway of the housing of the second assembly,
wherein the terminal engaging portions of the second assembly are configured to mate with the terminal engaging portions of the first-defined assembly.

17. The connectors as defined in claim 16, wherein each terminal engaging portion of the first-defined assembly comprises a plurality of flexible fingers and each terminal engaging portion of the second defined assembly a blade.

18. The connectors configured to transmit power as defined in claim 16 in combination with a first printed circuit board having a trace coupled to the body portion of each terminal of the first-defined assembly by a coupling, wherein the trace has a width which is greater than a width defined by the couplings and the heat sink of the first-defined assembly, and a second printed circuit board having a trace coupled to the body portion of each terminal of the second assembly by a coupling, wherein the trace of the second printed circuit board has a width which is greater than a width defined by the couplings and the heat sink of the second assembly.

19. A power connector comprising:
a first dielectric housing having a plurality of walls defining a plurality of passageways therethrough extending from a front end thereof to a rear end thereof, and a plurality of openings through one of the walls, respective openings being in fluid communication with the respective passageways;
a first assembly mounted within each passageway, each first assembly comprising a pair of terminals mounted within the respective passageway and a heat sink mounted between the terminals, each terminal having a body portion positioned within the passageway and a terminal engaging portion extending from the body portion, the body portions being adjacent to each other and spaced apart from each other, the terminal engaging portions being adjacent to each other, and the heat sink being positioned between the body portions and extending outward from the passageway of the housing, the heat sink of each assembly having an opening therethrough which extends from a front end thereof to a rear end thereof, and the respective opening in the housing is in fluid communication with the opening through the respective heat sink;
a second dielectric housing having a plurality of walls defining a plurality of passageways therethrough extending from a front end thereof to a rear end thereof; and
a second assembly mounted within each passageway of the second housing, each second assembly comprising a pair of terminals mounted within the respective passageway and a heat sink mounted between the terminals, each terminal of the second assembly having a body portion positioned within the passageway of the second housing and a terminal engaging portion extending from the body portion of the second assembly, the body portions of the second assembly being adjacent to each other and spaced apart from each other, the terminal engaging portions of the second assembly being adjacent to each other, and the heat sink of the second assembly being positioned between the body portions of the second assembly and extending outward from the passageway of the housing of the second assembly,
wherein the terminal engaging portions of the second assembly are configured to mate with the terminal engaging portions of the first assembly.

20. The power connector as defined in claim 19 in combination with a first printed circuit board having traces coupled to the body portion of each terminal of the first assembly by a coupling, wherein each trace has a width which is greater than a width defined by the couplings and the heat sink of the respective first assembly; and a second printed circuit board having traces coupled to the body portion of each terminal of the second assembly by a coupling, wherein each trace of the second printed circuit board has a width which is greater than a width defined by the couplings and the heat sink of the respective second assembly.
